(19) United States
(12) Patent Application Publication
(10) Pub. No.: US 2012/0282023 A1
(43) Pub. Date: Nov. 8, 2012

(54) ASSEMBLY ELEMENT FOR ENABLING AN ADJUSTABLE ASSEMBLY OF A DECORATIVE ELEMENT HAVING A HOUSING

(76) Inventor: Marc Riobe, Lille (FR)

(21) Appl. No.: 13/510,695

(22) PCT Filed: Dec. 22, 2009
(86) PCT No.: PCT/FR09/52657

§ 371 Date: Jul. 24, 2012

(30) Foreign Application Priority Data
Nov. 19, 2009 (FR) 0958174

(51) Int. Cl. H05K 5/02; G06F 1/16; F16B 5/06

(52) U.S. Cl. 403/364; 403/345

(57) ABSTRACT

An assembly element for enabling an adjustable assembly of a decorative element, such as a decorative plate, having a housing capable of containing an electronic apparatus, such as a computer, said assembly element comprising at least one means for attachment onto the outer surface. The assembly element comprising a first securing element capable of enabling the securing of the assembly element to the decorative element, said assembly element also having a second securing element capable of engaging with the at least one attachment means such as to enable the securing of the assembly element to the housing while maintaining a constant spacing between the assembly element and the housing.

### TECHNICAL FIELD

The object of the present invention is located in the field of cladding systems for a casing, and notably casings capable of containing an electronic appliance using electronic components, such as a computer, a DVD reader, or any other types of electric and/or digital appliances.

The object of the present invention finds advantageous applications in the field of decoration and more particularly in the field of decorative objects capable of containing an electronic appliance as described above.

The object of the present invention also finds advantageous applications in the design, luxury goods and fashion field by giving the possibility to the design, luxury goods and/or fashion industry of proposing claddings for casings or for decoration objects containing one or several electronic appliances as described above.

In the whole of the present description, by casing, is meant any types of container capable of containing at least one electronic appliance such as a computer, a DVD reader, or any other types of electric and/or digital appliances. Therefore this may be a casing of decoration objects, of decoration furniture, of housings or of any other types of container with an ornamental nature suitable for this purpose.

### STATE OF THE ART

Many computer cladding systems are generally known in the state of the art.

As an example, mention may be made of documents U.S. Pat. No. 5,941,617, US 2001/0054861 or further US 2008/0074834 which propose cladding systems consisting in panels with a decorative nature.

This kind of systems however has low modularity in terms of cladding. Indeed, it is difficult or even impossible to allow modular cladding of a computer with this kind of systems.

The cladding panels used in this kind of systems are actually simple panels, the shape and dimensions of which are conditioned by the computer itself.

These cladding panels are therefore directly proposed by computer manufacturers; and generally, cladding panels are pre-assembled directly to the computer through simple attachment means.

It may be noted that, in this kind of systems, the attachment means do not allow adjustment of the positioning of the cladding panel with the computer.

As mentioned above, it may also be noted that these attachment means do not allow good modularity of the cladding panels: assembling and disassembling the panels, as well as the re-cladding of such systems are complex.

Also, it may be noted that in this kind of systems, problems related to the cooling of electronic components of the computer impose the presence of ventilation grids directly on the cladding panels.

Such grids make the cladding systems unsightly.

Thus, it is generally seen that the teachings of the state of the art do not propose solutions allowing modular cladding of an electronic system such as a computer while taking into account the constraints related to ventilation of the electronic components in the casing of such a system.

### SUMMARY AND OBJECT OF THE PRESENT INVENTION

The object of the present invention is therefore to provide a simple and efficient solution to the aforementioned problems among other problems; the constraints related to costs and manufacturing being of course taken into consideration in the object of the present invention.

One of the technical problems solved by the object of the present invention consists of proposing a simple and easy-to-use solution; this solution notably proposing a modular cladding system for an electronic system while taking into account constraints related to the cooling of the electronic components of these systems.

For this purpose, the object of the present invention relates to an assembly element intended for a modular assembly of a decorative element, such as a decorative plate, with a casing capable of containing an electronic appliance, such as a computer, and at least including one attachment means on its outer surface.

The assembly element according to the present invention includes a first securing element capable of allowing the assembly element to be firmly secured to the decorative element.

The assembly element according to the present invention further includes a second securing element capable of cooperating with the means for attaching the casing in order to allow the assembly element to be firmly secured to the casing while maintaining a constant distance between the decorative element and the casing.

Such a layout thus gives the possibility of being able to easily clad in a modular way a casing such as a computer casing or an electronic appliance casing while taking into account cooling constraints related to proper operation, to the performances and lifetime of the electronic components of the computer or of the electronic appliance contained in the casing.

Indeed, this constant distance allows good circulation of air in the entire space between the casing and the decorative element; this circulation providing good cooling of the electronic components.

Advantageously, the first securing element includes a first receiving means, and the second securing element includes a first attachment means.

In this case, the first attachment means is capable of cooperating with the first receiving means in order to allow temporary assembly of the first securing element with the second securing element.

This alternative embodiment in which the first and second securing elements are capable of being temporarily assembled to each other allows improvement in the modularity of the cladding of the casing.

Advantageously, the first securing element is a plate which preferably is of a substantially square shape.

This plate has a first face, and a second face which is opposite to the first face and which is intended to be firmly secured with the decorative element.

Advantageously, the first receiving means is positioned on the first face.

According to an alternative embodiment of the present invention, the second face includes at least two positioning studs, each of the positioning studs being positioned in one of the corners of the second face.

This layout with positioning studs gives the possibility of avoiding relative sliding of the decorative element with respect to the assembly element because the positioning studs bear upon the decorative element.

Advantageously, the first securing element preferably includes a through-hole in its center.

This through-hole allows introduction of a long slender rod in order to firmly secure the assembly element with the decorative element.

The firm securing of the assembly element with the decorative element may also be accomplished by any other securing means such as an adhesive bond for example.

Advantageously, the second securing element is a cylindrical part, the first end of which includes a third attachment means.

In an alternative embodiment according to which the means for attaching the casing is a perforation, the third attachment means is deformable, and is able to be introduced into the perforation of the casing.

By introducing such a third attachment means into the perforation of the casing, the assembly element may be firmly secured with the casing.

According to an embodiment of the present invention, this firm securing is accomplished by fitting or by snap-on fastening of the third attachment means in the perforation of the casing.

Quite obviously, these may be any other means allowing two elements to be firmly secured to each other temporarily: screws, magnetic elements, etc.

Advantageously, in the alternative embodiment according to which the second securing element is a cylindrical part, the first attachment means notably consists in two lugs which are positioned at the second end of the second securing element and which extend in the plane formed by the base of the cylinder.

Still in this same alternative, the first receiving means is a hollow cylinder, the upper portion of which is open in order to allow introduction of the second end and which includes two L-shaped notches capable of receiving the lugs respectively.

In this case, the assembly between the first and second securing elements is accomplished by introducing the second end of the second securing element into the second receiving means of the first securing element; this introduction being accomplished according to a simple translation in which the second securing element is substantially perpendicular to the first securing element so that the lugs respectively slide into the first wing of the L of each of the two notches.

Next, it is sufficient to perform a rotation of the second securing element on itself so that the lugs respectively slide into the second wing of the L of each of the notches.

With such simple and intuitive kinematics, the first and second securing elements may be assembled together.

Advantageously, the first securing element includes a second attachment means and a second receiving means.

Thus, the first securing element allows an assembly element as described above, called here a first assembly element, to be assembled with another assembly element, called a second assembly element, including another first securing element capable of allowing said other assembly element to be firmly secured with the decorative element and including another second attachment means and another second receiving means.

This assembling between the first and second assembly elements is obtained by cooperation of the second attachment means of the first assembly element with the other second receiving means of the second assembly element, or by cooperation of the second receiving element of the first assembly element with the other second attachment means of the second assembly element.

Thus, when the second attachment means of the first assembly element is introduced into the other second receiving means of the second assembly element or vice versa, said first and second assembly elements may be assembled with each other.

Advantageously, the second attachment means consists in a rectilinear housing formed in the first securing element and both opposite edges of which each include a protrusion laid out so that each of the two protrusions is facing one opposite the other.

In the case when the other attachment means of the second assembly element also consists in another housing and two other protrusions as described above, the second receiving means consists in a rectilinear tab with a shape mating that of the other housing, and both opposite edges of which each include a first hole laid out for receiving one of the other protrusions.

Thus, with this layout the first assembly element may be attached in a same plane with the second assembly element.

Advantageously, the second receiving means further includes two second holes laid out so as to receive each of the other protrusions of the second assembly element in order to allow the first assembly element to be attached with the second assembly element.

In this case, the first assembly element forms a right angle with the second assembly element.

This configuration is particularly advantageous when it is desired to clad a casing having right angles.

Thus it is possible to cover casings with a parallelepipedal shape of any dimensions; this by using a plurality of assembly elements as described above and having the same dimensions.

Correlatively, the object of the present invention also relates to an assembly including a casing having at least one attachment means on its outer surface, at least one assembly element as described earlier, and a decorative element.

The object of the present invention thus has many advantages relatively to the state of the art, notably by allowing modular cladding of a casing capable of containing an electronic appliance; this cladding may be made with any type of decorative element having at least one planar surface.

The object of the present invention also provides consequent improvements as regards the use, assembling and mounting of such decorative elements with such a casing.

### SHORT DESCRIPTION OF THE FIGURES

Other features and advantages of the present invention will become apparent from the description below, with reference to the appended figures which illustrate an exemplary embodiment thereof, without any limitation and wherein:

FIGS. 1a to 1c consist in a plurality of schematic views illustrating the assembly element according to a particular embodiment of the present invention;

FIG. 2 illustrates a schematic sectional view of the assembly element according to a particular embodiment of the present invention;

FIG. 3 illustrates a casing including a plurality of perforations on its outer surface in order to allow the casing to be firmly secured with at least one assembly element according to the present invention, and containing an electronic appliance such as a computer or a DVD reader;

FIGS. 4a to 4b schematically illustrate two assembly elements attached together according to two possible alternatives, and FIG. 4c illustrates a detailed schematic view of the second receiving and attachment means according to a particular embodiment of the present invention;

FIGS. 5a and 5b illustrate a schematic view of an assembly according to two alternative embodiments, each of the assemblies including a casing, a decorative element and a plurality of assembly elements according to the present invention;

FIG. 6 illustrates an exemplary assembly containing an electronic appliance according to the present invention.

### DETAILED DESCRIPTION OF AN EMBODIMENT

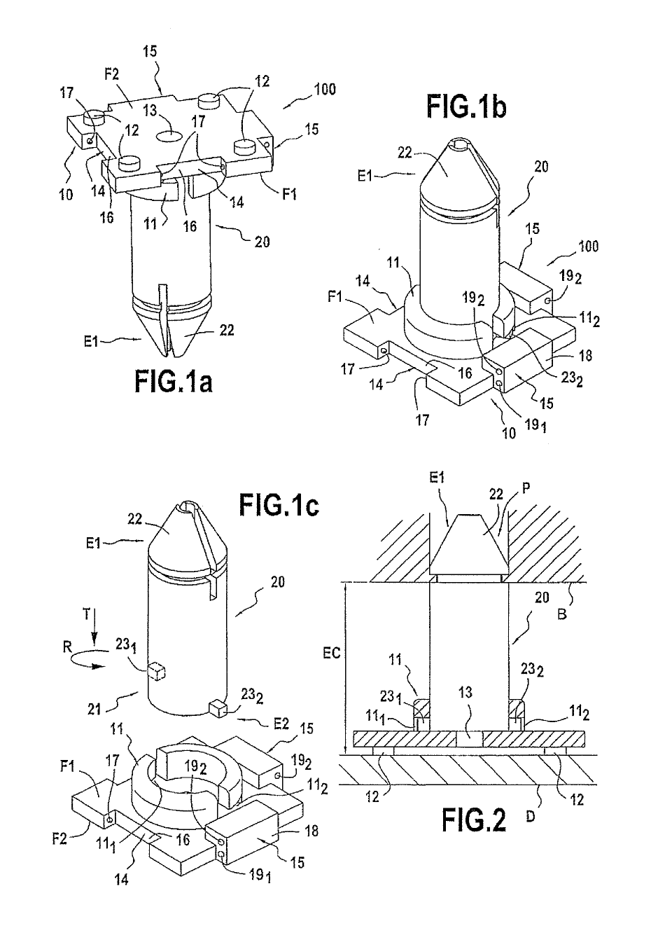

An assembly element according to a preferred embodiment of the present invention as well as an assembly including such an assembly element, a casing and a decorative element of the present invention will now be described in the following with joint reference to FIGS. 1 to 6.

One of the goals of the present invention is to allow modular cladding of an electronic appliance such as a computer, a DVD reader or any other types of electric and/or digital appliances in order to make it a decoration object.

Indeed, as mentioned above, the cladding systems of the state of the art do not allow modular cladding with several types of decorative elements: panels, half-spheres, or decorative elements having any types of shape and/or of volume.

Thus, electronic appliances are very often bulky, apparent and unsightly, and do not merge into the decoration of a room.

The object of the present invention therefore attempts to find a remedy to this drawback, and proposes an attractive solution giving designers and the luxury goods and fashion industry the possibility of cladding electronic appliances so as to transform them into decorative objects, or at the very least into objects which merge in the setting of a room.

Thus, in the example described here, it is possible to transform the appearance of an electronic appliance into a “Zen garden” as illustrated in FIG. 6.

Quite obviously, it should be understood that this exemplary decoration of the “Zen” garden is not limiting and that it is possible to obtain other types of decoration objects such as a frame for a painting, a lamp stand, etc.,

In order to attain these different goals, the object of the present invention deals with an assembly element 100 which is intended for modular assembly of a decorative element D with a casing B.

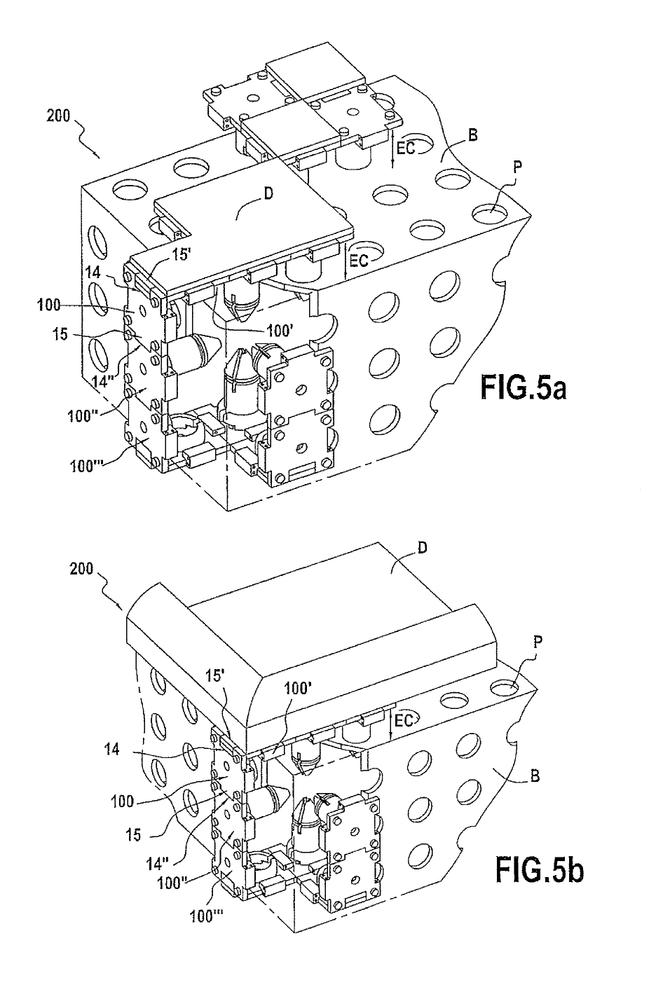

By decorative element in the sense of the present invention, and as illustrated in FIGS. 5a and 5b, is meant in the present description any types of plate, panel or any other decorative elements having any types of shape and/or of volume.

This decorative element D, optionally combined with other decorative elements D′, gives the possibility of obtaining the expected final result: a “Zen garden”, a frame for a painting, a lamp stand, etc.

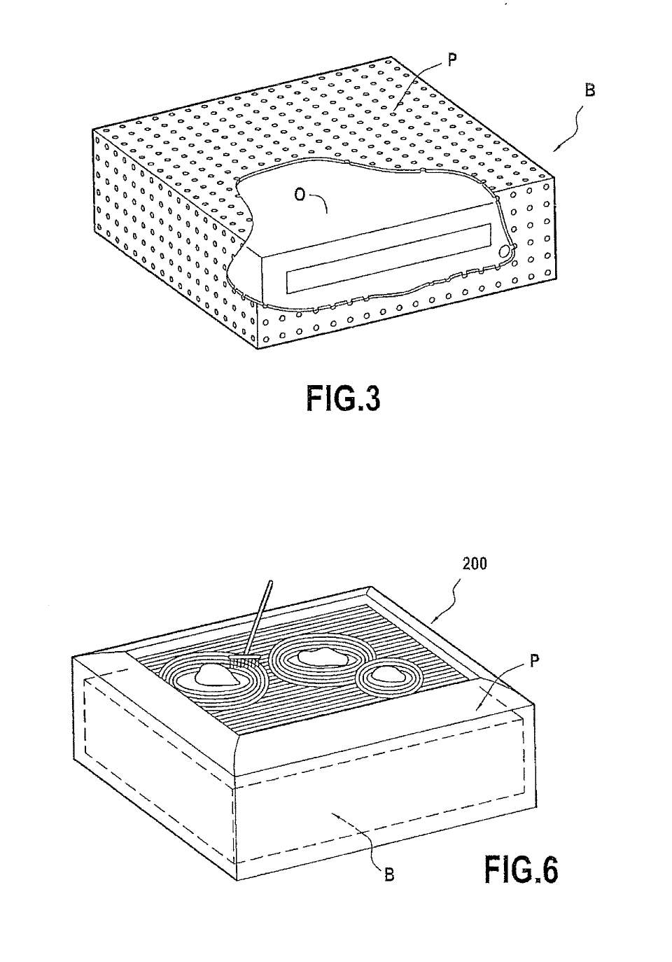

As mentioned above, and as illustrated in FIG. 3, the casing B is a container with a parallelepipedal shape capable of containing in its interior an electronic appliance O such as a computer.

In the example described here, the casing B includes a plurality of perforations P on its outer surface; these perforations P allow both assembling of the casing B with the assembly element 100.

Quite obviously, it will be understood that these perforations P may be replaced by any other types of attachment means capable of cooperating with the assembly element 100 so as to allow the casing to be assembled with the assembly element 100.

As illustrated in FIGS. 1a to 1c, 2 and 5a to 5b, the assembly element 100 according to the present invention includes a first securing element 10 capable of allowing the assembly element 100 to be firmly secured with the decorative element D.

Still as illustrated in FIGS. 1a to 1c, 2 and 5a to 5b, the assembly element 100 according to the present invention further includes a second securing element 20 capable of being partly introduced into one of the perforations P so as to allow the assembly element 100 to be firmly secured with the casing B while maintaining a constant distance EC between the decorative element D and the casing B; this difference EC giving the possibility of ensuring circulation of air for cooling the electronic components of the electronic appliance O.

Preferably, this distance is about of the order of 1 centimeter.

In the example described here, the first securing element 10 includes a first receiving means 11, and the second securing element 20 includes a first attachment means 21.

Advantageously, the first attachment means 21 is capable of cooperating with this first receiving means 11 in order to allow the first securing element 10 to be temporarily assembled with the second securing element 20.

More specifically, in the example described here, the first securing element 10 is a plate with a substantially square shape, the dimensions of which are 1 centimeter by 1 centimeter.

This plate has a first face F1 on which the first receiving means 11 is positioned and a second face F2 opposite to the first face F1 and intended to be firmly secured with the decorative element D.

In the embodiment described here, and as notably illustrated in FIG. 2, the second securing element 20 is a cylindrical part, the first end of which E1 includes a third deformable attachment means 22 which may be introduced into one of the perforations P of the casing B in order to allow the assembly element 100 to be firmly secured with the casing B.

In the example described here, this firm securing is accomplished by fitting or snap-on fastening of the third attachment means 22 in one of the perforations P of the casing B.

In order that the distance EC is of about of the order of 1 centimeter, the height of the cylinder is therefore approximately about of the order of 1 centimeter.

As mentioned above, the first receiving means 11 and the first attachment means 21 are capable of cooperating together in order to allow the first securing element 10 to be temporarily assembled with the second securing element 20.

In the example described here, and as notably illustrated in FIG. 2, the first attachment means 21 notably consists in two lugs 23₁ and 23₂ positioned at the second end E2 of the second securing element 20 and extending in the plane formed by the base of the cylinder; these lugs 23₁ and 23₂ being opposite to each other.

And, the first receiving means 11 is a hollow cylinder, the upper portion of which is open in order to allow introduction of the second end E2 of the second securing element 20.

The first receiving means 11 further includes two notches 11₁ and 11₂ positioned insider the cylinder all along its length, and capable of receiving the lugs 23₁ and 23₂ respectively.

In the example described here, both of these notches 11₁ and 11₂ are L-shaped.

Thus, in the example described here, the assembling between the first and second securing elements 20 is accomplished by introducing the second end E2 of the second securing element 20 into the second receiving means 11 of the first securing element 10.

As illustrated in FIGS. 1b and 1c, this introduction is accomplished according to simple translation T in which the second securing element 20 is substantially perpendicular to the first securing element 10 so that the lugs 23₁ and 23₂ may respectively slide in the first wing of the L of each of the two notches 11₁ and 11₂.

Next, it is sufficient to perform a rotation R of the second securing element 20 on itself so that the lugs 23₁ and 23₂ respectively slide in the second wing of the L of each of the notches 11₁ and 11₂.

By these two successive simple and intuitive movements T and R, an operator may easily assemble between the first 10 and the second 20 securing elements.

In the example described here, and as notably illustrated in FIGS. 1a and 2, the second face F2 includes four positioning studs 12; each of them being positioned in one of the corners of the second face F2.

In the example described here, and as notably illustrated in FIGS. 1a and 2, the first securing element 10 includes in its center a through-hole 13 allowing introduction of a long slender rod (not shown here) for firmly securing the assembly element 100 with the decorative element D.

In order to allow cladding of any types of casing having any dimensions with a single part, it is preferably to be able to allow assembly of the assembly elements so that these assembly elements are in the same plane, and these assembly elements are perpendicular to each other.

One of the goals of the present invention is to solve this assembly constraint which may be described as a bidirectional assembly.

Another constraint also lies in the fact that it is preferable to keep the same overlapping surface during the assembling regardless of the configuration (planar or at right angles) of this assembly so as to be able to cover the whole surface uniformly with elements having the same dimensions.

For this purpose, the first securing element 10 includes in a characteristic way, a second attachment means 14 and a second receiving means 15.

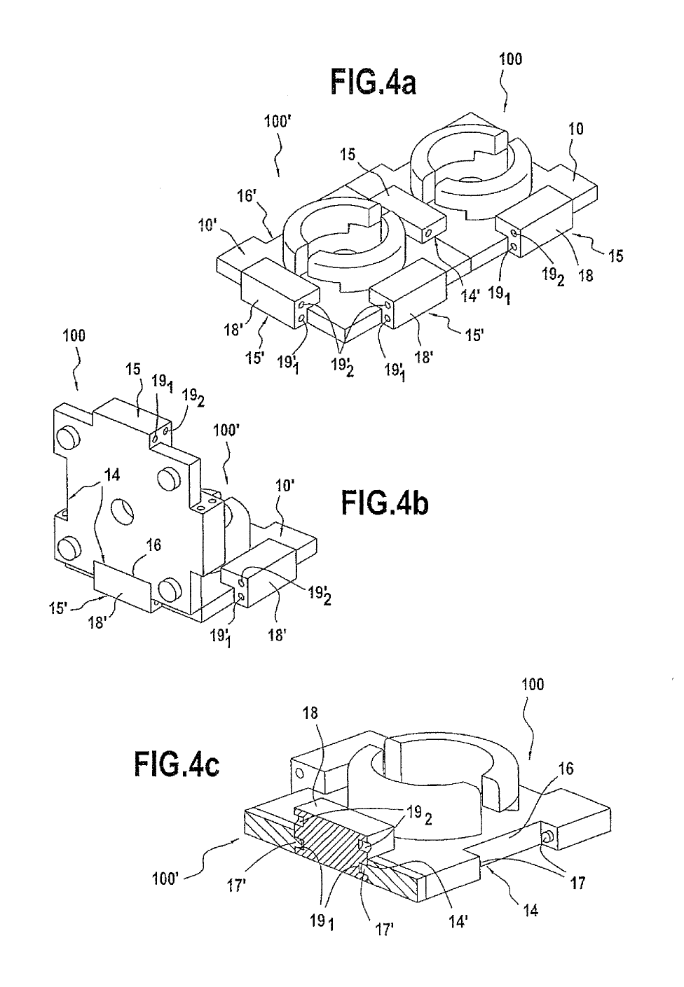

As illustrated in FIGS. 4a to 4c, these second attachment 14 and receiving 15 means are laid out so as to allow the assembly element 100 to be assembled with at least one other assembly element 100′ (or 100″) including another first securing element 10′ (or 10″) capable of allowing the other assembly element 100 to be firmly secured with the decorative element D and including another second attachment means 14′ (or 14″) and another second receiving means 15′ (or 15″).

This assembling between both assembly elements 100 and 100′ (or 100″) is equally obtained by the cooperation of the second attachment means 14 with the other second receiving means 15′ (or 15″) (illustrated in FIG. 4b), or by the cooperation of the second receiving element 15 with the other second attachment means 14′ (or 14″) (as illustrated in FIG. 4a).

Structurally, and in the example described here, and illustrated in more details in FIG. 4c, the second attachment means 14 consist in a rectilinear housing 16 formed in the first securing element 10 and both opposite edges of which each include a protrusion 17 laid out so that each of the two protrusions 17 is facing each other, one opposite to the other.

In the example described here, the other attachment means 14′ (or 14″) of the other assembly element 100′ (or 100″) also consists in another housing 16′ (or 16″) and two other protrusions 17′ (or 17″).

And, the second receiving means 15 consists in a rectilinear tab 18 with a shape mating that of the other housing 16′ (or 16″), and both opposite edges of which each include a first hole 19₁ laid out for receiving one of the other protrusions 17′ (or 17″).

As illustrated in FIG. 4a, this layout allows attachment in a same plane of the assembly element 100 with said other assembly element 100′ (or 100″).

In the example described here, the other receiving means 15′ (or 15″) of the other assembly element 100′ (or 100″) also consists in another rectilinear tab 18′ (or 18″) with a shape mating that of the housing 16, and both opposite edges of which each include another first hole 19₁′ (or 19₁″) laid out for receiving one of the protrusions 17.

In the example described here, the second receiving means 15 further includes two second holes 19₂ laid out for each receiving one of the protrusions 17′ (or 17″).

As illustrated in FIG. 4b, this layout allows attachment of the assembly element 100 with another assembly element 100; this so that the assembly element 100 forms a right angle with the other assembly element 100′.

Thus, the object of the present invention gives the possibility of obtaining an assembly element 100 which is particularly simple to use, and adapted for designing and manufacturing any types of decoration object which may contain an electronic appliance O, and this in an aesthetic, discreet and sometimes even clever way.

The advantages provided by the different means of the present invention provide particularly advantageous results in the Field of design, luxury goods and fashion.

Thus, as an example, in hotel halls, in restaurants or in shops or in any other location in which a computer or an electronic appliance is found, it will be possible to merge this computer or this electronic appliance into the setting, and this in an original and discreet way.

Further, such an assembly element has advantages notably in terms of costs, ease of use and assembly.

It should be observed that this detailed description deals with a particular embodiment of the present invention, but this description by no means has any limitation with regard to the object of the invention; quite on the contrary, it has the goal of removing any possible inaccuracy or any wrong interpretation of the following claims.

1. An assembly element intended for a modular assembly of a decorative element such as a decorative plate, with a casing-capable of containing an electronic appliance, such as a computer, and including at least one attachment means on its outer surface, said assembly element including a first securing element capable of firmly securing said assembly element with the decorative element, wherein
said assembly element further includes a second securing element capable of cooperating with the attachment means in order to allow firm securing of said assembly element with the casing while maintaining a constant distance between the decorative element and the casing.

2. The assembly element according to claim 1, wherein the first securing element includes a first receiving means and wherein the second securing element includes a first attachment means,
so that the first attachment means is capable of cooperating with said first receiving means in order to allow the first securing element to be temporarily assembled with the second securing element.

3. The assembly element according to claim 2, wherein the first securing element is a plate, preferably with a substantially square shape, having a first face and a second face opposite to the first face and intended to be firmly secured with the decorative element.

4. The assembly element according to claim 3 wherein the first receiving means is positioned on the first face.

5. The assembly element according to claim 3, wherein the second face includes at least two positioning studs, each of the positioning studs being positioned in one of the corners of the second Face,
so as to avoid relative sliding of the decorative element with respect to the assembly element.

6. The assembly element according to claim 1 wherein the first securing element includes, preferably at its center, a through-hole allowing introduction of a long slender rod in order to firmly secure the assembly element with the decorative element.

7. The assembly element according to claim 1, the attachment means of the casing being a perforation, wherein the second securing element is a cylindrical part, the first end of which includes a third attachment means capable of being introduced into the perforation of the casing in order to allow firm securing of the assembly element with the casing.

8. The assembly element according to claim 2, the second securing element being a cylindrical part, wherein the first attachment means notably consists in two lugs positioned at the second end of the second securing element and extending in the plane formed by the base of the cylinder and wherein the first receiving means is a hollow cylinder, the upper portion of which is open in order to allow introduction of said second end and which includes two notches with the shape of an L capable of receiving said lugs respectively.

9. The assembly element according to claim 1, wherein the first securing element includes a second attachment means and a second receiving means, so as to allow said assembly element to be assembled with another assembly element including another first securing means capable of allowing said other assembly element to be secured with the decorative element and including another second attachment means and another second receiving means, said assembling between both assembly elements being obtained by cooperation of said second attachment means with said other second receiving means or by cooperation of said second receiving element with said other second attachment means.

10. The assembly element according to claim 9, wherein the second attachment means consists in a rectilinear housing formed in the first securing element and both opposite edges of which each include a protrusion laid out so that each of the two protrusions is facing each other, one opposite to the other.

11. The assembly element according to claim 10, the other attachment means of the other assembly element also consisting in another housing and two other protrusions, wherein the second receiving means consists in a rectilinear tab with a shape mating that of the other housing, and both opposite edges of which each include a first hole laid out so as to receive one of the other protrusions, so as to allow attachment in a same plane of the assembly element with said other assembly element.

12. The assembly element according to claim 11, wherein the second receiving means further includes two second holes laid out so as to each receive one of the protrusions in order to allow attachment of the assembly element with another assembly element, so that the assembly element forms a right angle with the other assembly element.

13. An assembly including a casing having at least one fastening means on its outer surface, an assembly element according to claim 1, and a decorative element, the first securing element allowing the assembly element to be firmly secured with the decorative element, and the second securing element cooperating with the fastening means in order to allow the assembly element to be secured with the casing,
so as to allow modular assembling of the decorative element with the casing while maintaining a constant distance between the decorative element and the casing.

14. An assembly element intended for a modular assembly of a decorative element such as a decorative plate, with a casing capable of containing an electronic appliance, such as a computer, and including at least one attachment means on its outer surface, said assembly element including a first securing element capable of firmly securing said assembly element with the decorative element. wherein said assembly element further includes a second securing element capable of cooperating with the attachment means in order to allow firm securing of said assembly element with the casing while maintaining a constant distance between the decorative element and the casing, wherein the first securing element includes a first receiving means and wherein the second securing element includes a first attachment means, so that the first attachment means is capable of cooperating with said first receiving means in order to allow the first securing element to be temporarily assembled with the second securing element. wherein the second securing element being a cylindrical part, wherein the first attachment means notably consists in two lugs positioned at the second end of the second securing element and extending in the plane formed by the base of the cylinder and wherein the first receiving means is a hollow cylinder, the upper portion of which is open in order to allow introduction of said second end and which includes two notches with the shape of an L capable of receiving said lugs, respectively, and wherein the first securing element includes, preferably at its center, a through-hole allowing introduction of a long slender (rod in order to firmly secure the assembly element with the decorative element.

15. An assembly element intended for a modular assembly of a decorative element such as a decorative plate, with a casing capable of containing an electronic appliance, such as a computer, and including at least one attachment means on its outer surface, said assembly element including a first securing element capable of firmly securing said assembly element with the decorative element. wherein said assembly element further includes a second securing element capable of cooperating with the attachment means in order to allow firm securing of said assembly element with the casing while maintaining a constant distance between the decorative element and the casing, wherein the first securing element includes a first receiving means and wherein the second securing element includes a first attachment means, so that the first attachment means is capable of cooperating with said first receiving means in order to allow the first securing element to be temporarily assembled with the second securing element. and wherein the first securing element includes a second attachment means and a second receiving means, so as to allow said assembly element to be assembled with another assembly element including another first securing capable of allowing said other assembly element to be secured with the decorative element and including another second attachment means and another second receiving means, said assembling between both assembly elements being obtained by cooperation of said second attachment means with said other second receiving means or by cooperation of said second receiving element with said other second attachment means.
